(19) United States
(12) Patent Application Publication
(10) Pub. No.: US 2008/0253070 A1
(43) Pub. Date: Oct. 16, 2008

(54) FOLDABLE ELECTRONIC DEVICE HAVING OPTICAL DATA CONNECTION OF HOUSING PARTS

(75) Inventors: Hannu Rissanen, Oulu (FI); Jussi Pitkonen, Keltasirkuntie (FI)

Correspondence Address: MORGAN & FINNEGAN, L.L.P., 3 WORLD FINANCIAL CENTER, NEW YORK, NY, 10281-2101, US

(73) Assignee: NOKIA CORPORATION, Espoo (FI)

(21) Appl. No.: 11/734,104

(22) Filed: Apr. 11, 2007

(51) Int. Cl. H05K 7/00

(52) U.S. Cl. 361/681; 361/679

(57) ABSTRACT

An electronic device includes: a first housing part including first electronic components; a second housing part including second electronic components; a hinge element foldably connecting the first and the second housing parts, wherein the first housing part and the second housing part are capable of taking at least a first and a second position in relation to each other; a first optoelectronic device connected with the first electronic components; and a second optoelectronic device connected with the second electronic components, wherein the hinge element constitutes a light guiding element adapted to couple the optoelectronic devices at least in the first position and the second position.

Various embodiments of the present invention relate to an electronic device comprising two or more housing parts which are foldable in relation to each other, the device comprising an optical arrangement enabling optical data communication between electronic components located in the housing parts. These particularly relate to mobile electronic devices with two housing parts which can be folded, like mobile phones of the flip type.

### TECHNICAL FIELD

Mobile electronic devices comprising two movable housing sections or parts have become rather popular recently. Prominent examples are the so-called flip- or collapsible phones. The housing parts of such phones usually can take at least two positions, wherein in a first (closed) position only the most important display and/or control elements are accessible, for example the display together with keys for taking/rejecting calls and viewing incoming messages. In order to render the phone fully operational, that is, to enable the user to access all control and/or display elements, the housing parts are folded open in relation to each other, taking the second (open) position exposing e.g. the full keypad and/or main display.

Flip-, collapsible or foldable phones usually also have a first closed position wherein the housing parts are located on top of each other. In these phones the upper housing part can be folded open to render the phone fully operational.

Such phones usually comprise a bottom part housing the keypad, bottom connector etc., and a top part housing the display, camera etc. Advantages of such phone structures include an enhanced available area for both display and keypad, that is, the display and control elements can be designed larger. In this manner larger scale displays and keypads/keys can be incorporated in such devices, enabling improved usability. Through the use of the foldable housing parts these advantages are though combined with a small footprint of the (folded/closed) phone, maintaining a good portability of the device. However, a disadvantage of such phones is that the two parts require a data connection in order to exchange data, e.g. from a camera located in the top part to the processor located in the bottom part, or the processor in the bottom part to the display in the top part.

In such flip phones usually flexible cables are used to interconnect the top and bottom part. The cables require careful design to fulfil mechanical durability and electrical reliability requirements, especially when used in high data rate applications. High-speed interconnections are needed because display and camera resolutions are constantly increasing, e.g. for mobile TV applications as DVB-H and megapixel cameras. This requirement is even more aggravated by the trend of serialization of the data connections, which are still mainly parallel interconnections used frequently nowadays. The serialization trend is inter alia caused by the increasing miniaturization. Currently flexible cables and micro coax cables are used, which require much space on the printed wiring board (PWB) and increase the product volume. Their design is rather difficult for high data rates, particularly in the gigabit per second area. Also they are subject to mechanical wear which may finally result in breakage of the data connection, rendering the respective electronic device inoperative.

### SUMMARY OF THE INVENTION

Various embodiments of the present invention provide an electronic device with foldable housing parts, wherein the interference-prone wired connections between the housing parts are replaced by connections which are more reliable from a mechanical point of view and which enable higher data rate applications. Furthermore various embodiments of the invention provide such a device wherein only one optical transmitter/receiver is required per housing part.

According to an aspect of one embodiment of the invention an electronic device is provided, comprising:
a first housing part comprising first electronic components;
a second housing part comprising second electronic components;
a hinge element foldably connecting said first and said second housing part; wherein said first housing part and said second housing part are capable of taking at least a first and a second position in relation to each other;
a first optoelectronic device connected with said first electronic components; and
a second optoelectronic device connected with said second electronic components; wherein said hinge element constitutes a light guiding element adapted to couple said optoelectronic devices at least in said first position and said second position.

Replacing the error-prone unreliable mechanical wire connections with optical data links provides an improved reliability in such electronic devices, while at the same time enabling higher data rates. Furthermore the arrangement of the exemplary embodiment of the present invention does not need more than one optoelectronic transmitter/receiver or transceiver per housing part, thus saving costs and area on the printed wiring board. Providing a hinge element constituting the light guiding element allows a more compact, lighter and more flexible design of (mobile) electronic devices. Additional light guiding elements are not required, as the light guiding function is already provided by the hinge element. Still further advantages of such an arrangement will be explained in more detail in the detailed description of embodiments of the present invention.

The first electronic components may comprise the main controller (also called “engine”) or CPU of the device, memory means, control elements like a keypad, 4-way navigation key and other electronic components used in electronic devices. The second electronic components may comprise the main display of the device, a still or video camera, microphone, a WLAN or Bluetooth module and auxiliary control elements like call taking/rejecting keys, a key for scrolling through received messages and the like. That is, there may be electronic components located in each housing part which require a data connection with electronic components located in the other housing part. The data connection can both be uni-directional as well as bi-directional, depending on the actual combination of electronic components.

According to an exemplary embodiment said first housing part and said second housing part are capable of being folded into any position between said first and said second position, and said light guiding element is adapted to couple said optoelectronic devices in any of said positions.

This embodiment ensures that the data link between the housing parts will not be discontinued during folding the device open or close. In other embodiments the data connection may be arranged to be established only in said first and said second position (or an additional, but limited number of positions).

According to an exemplary embodiment said first optoelectronic device is an optical emitter and said second optoelectronic device is an optical receiver. This embodiment allows keeping the manufacturing costs of the device low. It is suitable for devices requiring only a uni-directional data link between housing parts, e.g. a device only having a display on the upper housing part, or in other words only passive components.

According to an exemplary embodiment said first and second optoelectronic devices are optical transceivers. In contrast this embodiment is also suitable for devices requiring a bi-directional data link between the housing parts. This applies to devices having active electronic components in both housing parts, e.g. a camera module and additional call handling buttons on the upper housing part, and a CPU and main keyboard on the bottom part.

According to an exemplary embodiment light guiding element is further adapted to radiate, at least in one position of said first and said second housing part, light emitted from said at least one optical emitter out of said hinge element. This embodiment allows different advantages. First it is possible to use the hinge element as emitter for e.g. an IrDA or other infra-red or generally optical data transmission port. No additional components will be necessary for providing an IrDA port then, as the emitter within the hinge element is already capable of radiating light. Secondly this embodiment enables to provide additional optical effects, e.g. for incoming call/message signalling, or for providing an illuminated logo. For this purpose the light emitter can readily be used, if it operates (also) in the visible wave length area. However, it is as well possible to add an additional light emitter operating in the visible wave length area.

Having an additional visible light emitter also allows the user to perceive easily when the hinge element is dusty, dirty or scratched, which may cause data transfer errors. The user is thus informed about this potential reason for operation failures of the electronic device and he can then clean/polish the outside of the hinge element to restore reliable data transmission. With invisible infra-red radiation this would not be possible in this manner.

According to an exemplary embodiment said at least one optical emitter is capable of emitting visible light. Generally visible light will have a wave length of around 380-780 nm. It will be appreciated that the invention is not limited to a particular wave length area.

According to an exemplary embodiment the device further comprises a light shielding element arranged on said hinge element, wherein said light shielding element shields at least a part of light emitted by one of said optoelectronic devices from being radiated outside of said hinge element at least in one position of said first and said second housing part.

This light shielding element provides both a shield preventing light from being radiated to the outside as well as preventing any optical radiation from entering the light guiding element in order to avoid any interference. It can be implemented as a complete shielding, i.e. preventing light from being emitted in all possible positions of the housing parts. However, it can also be implemented to perform the shielding only in a limited number of positions. For example it can be provided to shield the light only when the foldable phone is in its open position. The shielding can also provide protection of the hinge element against dirt and scratches.

According to an exemplary embodiment said light guiding element and/or said light shielding element are arranged to be capable of forming an illumination pattern visible on the outside of said hinge element at least in one position of said first and said second housing part.

That is, the light emitter itself can form an illuminated logo like the specific model of the electronic device (Nokia 8850i or like). Or the light shielding element can comprise light-permeable portions to form the logo. It is to be noted that the arrangement may be only “capable” of providing the logo in that an illuminated logo may not be visible all the time, i.e. it is only visible when the corresponding light emitter is active. For example the logo can be activated only when the keyboard illumination is active as well. The logo can also be provided in a combination of shielding element and form of the light emitter.

In the context of various embodiments of the present invention the term “logo” is to be understood as including both aesthetic as well as functional optical indications. For example the logo (or part of it) can be used to indicate incoming short messages, calls etc., or other operating states of the electronic device (low battery level etc.).

According to an exemplary embodiment said device is one of:
a mobile phone;
a personal digital assistant, PDA;
a gaming terminal or mobile gaming terminal;
a personal navigation assistant, PNA; and
a notebook computer.

According to an exemplary embodiment said first and said second electronic components comprise at least one of:
a central processing unit, CPU;
a memory unit;
a display;
control keys;
a camera module;
a wireless local area network, WLAN, module;
a Bluetooth module;
a cellular transceiver;
a microphone;
a speaker; and
vibra or other haptic devices.

### BRIEF DESCRIPTION OF THE DRAWINGS

The invention can be more fully understood by the following detailed description of exemplary embodiments, when also referring to the drawings, which are provided in an exemplary manner only and are not intended to limit the invention to any particular embodiment illustrated therein. In the drawings FIG. 1 shows a first exemplary embodiment of an electronic device according to the invention in a closed position;

FIG. 2 shows a second exemplary embodiment of an electronic device according to the invention in an open position;

FIG. 3 shows a cross-section view of a device as in FIG. 2, in a closed position; and

FIG. 4 shows another exemplary embodiment of an electronic device according to the invention in a closed position.

### DETAILED DESCRIPTION OF THE INVENTION

It should be noted that the following description will focus on the example of a mobile phone as the electronic device, although the invention is not limited to particular electronic devices. The figures will be depicted schematically only. That is, common elements present in a mobile phone or like devices are not shown here, like displays, control keys, batteries etc. Also the dimensions depicted here are only to be understood as illustrative, and should not be construed as limiting for the present invention. In the figures certain dimensions (e.g. the distance between top and bottom housing part) may intentionally be exaggerated, in order to improve the intelligibility.

In FIG. 1 an exemplary first embodiment of the present invention is depicted, in this case for a so-called flip or foldable phone, comprising a first or bottom housing part 2 and a second or top housing part 6, which are foldably connected via a hinge element 18. In this figure the phone is shown in its first or closed position, wherein the housing parts 2 and 6 are located on top of each other.

On the bottom part 2 an optoelectronic transmitter 10 is arranged, which is electrically connected with first electronic components 4 accommodated within the bottom part 2. Such electronic components may comprise the bottom connector of the phone, memory devices, the controller or CPU, a keypad and other control keys/means etc. That is, the (electronic interface of) transmitter 10 is connected with first electronic components 4 which require a data connection with other second electronic components located in the top housing part 6.

In this embodiment the second housing part 6 is substantially identical with housing part 2, in a reversed manner. That is, it comprises an optoelectronic receiver 12 having its electronic interface connected with second electronic components 8 located within the housing part 6.

The hinge element 18 connecting the two housing parts 2 and 6 constitutes a light guiding element 14. The light guiding element 14 is adapted to direct light (indicated by the arrows) emitted by the transmitter 10 such that the light exits the light guiding element to be received by receiver 12. The light guiding element 14 is in the form of an optical “drum”, which by means of diffraction and/or reflection (e.g. using small prisms suitably arranged on the circumference thereof) directs light from the transmitter 10 such that it exits the drum where the receiver 12 is located. The full width of the drum can be used for optical transmission, thus increasing the reliability, because a small amount of scratches or dirt will not substantially disturb the optical transmission. It is to be noted that the light guiding element is an integral part of the hinge element, in other words, the light guiding element forms (at least part of) the hinge element. The light guiding element and hinge element are combined in this manner, instead of having some light guiding element provided additionally to the hinge.

In the embodiment in FIG. 1 a light shielding element 16 is located surrounding the hinge element 18, in order to prevent light from being emitted outside of said hinge element 18, and at the same time preventing any interfering optical radiation from entering the optical drum. In this manner the optical drum is also protected against dirt, dust and scratches. It will be apparent that the shielding element 16 is constructed such that it is able to perform the shielding also in the open position of the phone (not shown).

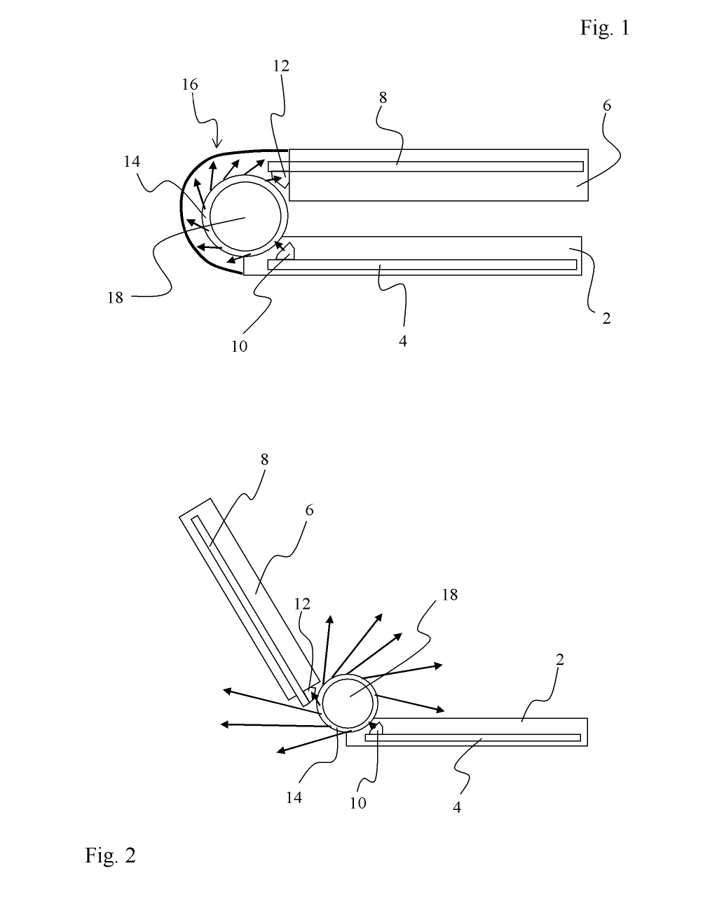

In FIG. 2 another exemplary embodiment of the invention is depicted. Here a flip phone basically similar to the one in FIG. 1 is illustrated in open position where the two housing parts 2 and 6 are folded open, exposing e.g. the keypad and main display etc. The difference in this embodiment is that no light shielding element is provided around the hinge element 18. Other parts of this embodiment are identical to the one depicted in FIG. 1. It is to be noted that the optical drum 14 is arranged to guide light emitted by the emitter 10 to exit the drum at an angle suitable for enabling the receiver 12 to receive the light.

Due to the nature of optical light guides it is principally also possible to transport light in the opposite direction, that is, from receiver 12 to transmitter 10. In advanced embodiments the transmitter 10 and receiver 12 are replaced by optoelectronic transceivers enabled to both send and receive light. In this case also a (bi-directional) data connection between the transceivers 10 and 12 is enabled by the present invention. However, in the figures only the direction from emitter 10 to receiver 12 is depicted.

It is also possible to provide multiple light guiding elements within the drum, e.g. cylindrical sections thereof, wherein each section is optimized for an individual light path. For example a first light path is optimized for uni-directional transmission from the transmitter in the bottom housing part to the receiver in the upper housing part, whereas a second light path is optimized for unidirectional transmission in the reverse direction (assuming that the upper housing part comprises another transmitter discrete from or integral with the receiver, and the bottom housing part comprises another receiver also discrete from or integral with the transmitter).

An example of an embodiment having only a uni-directional connection from transmitter 10 to receiver 12 may be a phone having the keypad, memory, CPU etc. in the bottom housing part 2, and just the display in the top housing part 6. In that case the unidirectional link is sufficient, as usually no signals need to be sent from the display unit back to the CPU or like. It should be noted that a required power connection for providing the electric energy will usually be of a wired type. In the context of various embodiments of the present invention it is also possible to use wired connections for a portion of signals to be transported between different housing parts, in addition to the optical connection. For example certain control data might be transported by wires/cables, while the main (payload) data will be transported by the optical connection.

It is also possible to provide the upper (or generally any) housing part with its own power supply. In this case no power connections are necessary. In principle any contactless power connection is also possible, like inductive, capacitive, optical coupling of the housing parts etc.

Furthermore it is common that the microphone (for voice calls etc.) is built into the bottom part 2 of the housing, while the corresponding speaker is built into the top housing part 6. Also in this case it is not required to have a bi-directional link, as the microphone is already in the housing part where usually the main controller/CPU is located, such that a direct wired connection can easily be provided. The speaker in turn is only required to receive audio data and usually does not send back any data, such that the uni-directional data connection provided by the embodiment with the combination of transmitter 10/receiver 12 only is sufficient.

In contrast, as an example of a slider phone requiring a bi-directional link a phone having control keys and e.g. a camera/microphone incorporated in the top housing part 6 shall be mentioned. This also entails that transmitter 10 and receiver 12 are both actually transceivers with sending as well as receiving capability. In this case signals originating from the upper control keys (e.g. call taking/rejecting, viewing of messages) and/or image/audio data from the camera/microphone have to be transported from the top housing part 6 to the CPU or main controller of the phone located in the bottom part 2. Another example of a device requiring the bi-directional data link could be a wireless interface like a Bluetooth module or infra-red interface located in the top housing part 6.

A bi-directional connection can e.g. be achieved in a full-duplex manner by adding a second optical link in parallel to the first one, using the same light path(s) by using different colors/wavelength or by utilizing a half duplex transmission mode (only one end sends at a time, as e.g. used in IrDA).

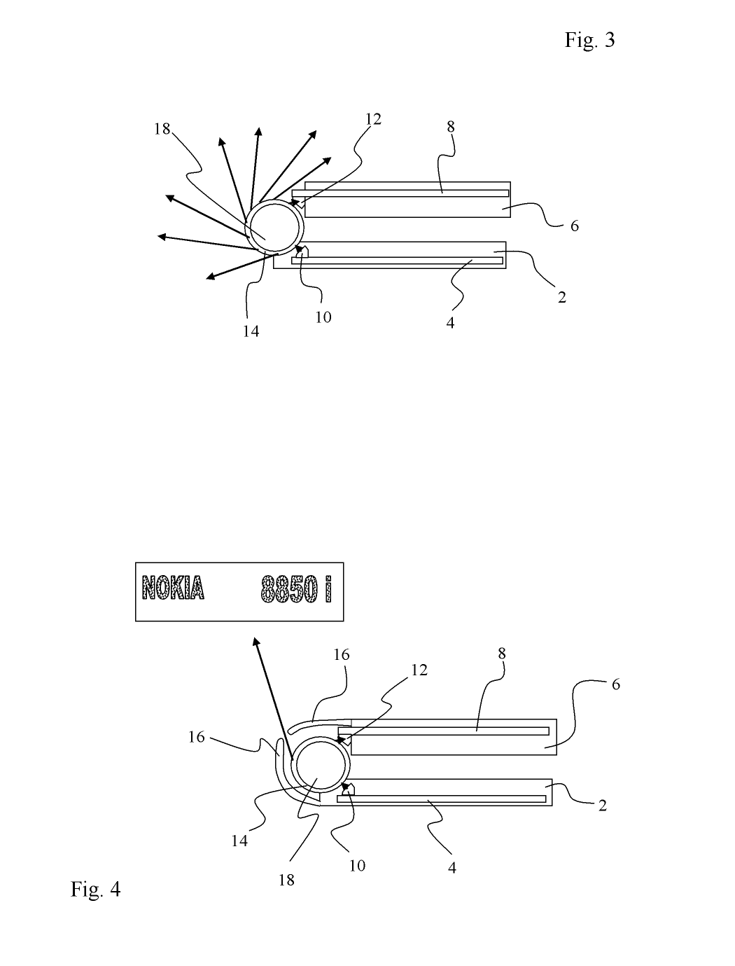

In FIG. 3 the embodiment of FIG. 2 is shown in a closed position of the flip phone.

FIG. 4 illustrates another exemplary embodiment of the present invention. This embodiment is basically similar to the one depicted in FIG. 1, with the exception that the light shielding element 16 is designed differently. In this embodiment it comprises an aperture being arranged for letting light exit the optical drum 14. The aperture can be in the form of a logo, as illustrated in the upper left of this figure. Thus an illuminated logo can be provided without requiring additional components. The illuminated logo can also be used to optically indicate certain operating conditions of the electronic device, e.g. incoming messages/calls, low battery level etc. This of course requires that the optical transmitter(s) in the electronic device operate at least partly in the visible wavelength area.

However, this embodiment can also be used to provide the above mentioned IrDA port or other optical interface, wherein the used wavelengths must not necessarily be in the visible domain.

In case the transmitter 10 and receiver 12 are infra-red optoelectronic devices infra-red transparent windows can be provided instead of the aperture on the light shielding element, in order to allow a transmission of the (infra-red) light. Infra-red light (IR) may be used due to the reason that the user should not be disturbed by any visible light being emitted from the open phone. However, also visible light may be used instead. For example this could be used as a design or fun feature, in a similar manner as the small LED flash stickers blinking responsively to the electromagnetic radiation emitted from a mobile phone antenna.

In this case it may be advantageous to provide the transceiver 10 with some standard infra-red interface protocol like IrDA and the like, at least to be supported in the one position. In this manner a useful wireless data link for synchronizing data between the mobile phone and a PC, PDA or the like can be provided without requiring an additional IR emitter.

In various embodiments of the present invention all kinds of optoelectronic devices can be used, for example (infra-red) photo diodes and transistors, and also laser diodes and light emitting diodes together with the respective receiver devices. It should also be noted that all optical devices such as lenses, mirrors, prisms, parabolic/elliptic mirrors and the like can be used with the various embodiments of the present invention when appropriate.

Lenses for correcting/improving the light path(s) can also be used, e.g. at the entrance or exit of the light guiding element/optical drum, or be connected directly with the optoelectronic transmitter/receiver/transceiver, e.g. for providing a substantially linear or non-divergent exit/entry path of light exiting/entering the respective devices. Therefore suitable lenses and also other optical devices can be used to obtain the desired/required light path.

Various embodiments of the present invention provide an electronic device wherein the data connection between two movable housing parts does not comprise any mechanically stressed parts like flexible cables. No additional components are needed for the data connection, as the hinge element constitutes a light guiding element allowing the optical data connection. For the required power connection cables can be used, which are reliable for this purpose, or an arrangement with sliding contacts, e.g. as part of the folding mechanism, can be used. Also inductive or capacitive coupling may be used.

Various embodiments of the invention furthermore enable high-speed data transfer in conjunction with small space requirements. In addition the optical media or light guiding element, respectively, is not susceptible to any electromagnetic interference (EMI), although a receiver device itself may still be susceptible thereto and require appropriate shielding. As the actual connection between the housing parts is an optical interface not necessarily requiring a physical connection, instead of a wired connection, various embodiments of the invention may even make the production of corresponding devices more flexible, as the different housing parts do not need to be joined or brought in close proximity preliminarily for attaching the cables for the data connection.

It should be apparent that the present invention can also be applied to electronic devices with more than two housing parts which are foldable. For example it can be applied to a foldable phone having two main housing parts and a camera module that can be turned 180° for capturing self-portraits of the user of the device. Also the invention is not to be limited to mobile phones or generally mobile devices only. It can be used in any mobile or stationary electronic device comprising two or more housing parts which are foldable in relation to each other, and wherein a data connection between the housing parts is required. For example also in base station hardware where an opening cover includes buttons, controls, displays or like. Another example is a car navigation system including a foldable screen and/or keyboard/control or input elements.

1. Electronic device, comprising:
a first housing part comprising first electronic components;
a second housing part comprising second electronic components;
a hinge element foldably connecting said first and said second housing part;
wherein said first housing part and said second housing part are capable of taking at least a first and a second position in relation to each other;
a first optoelectronic device connected with said first electronic components;
and
a second optoelectronic device connected with said second electronic components;
wherein said hinge element constitutes a light guiding element adapted to couple said optoelectronic devices at least in said first position and said second position.

2. Device according to claim 1, wherein said first housing part and said second housing part are capable of being folded into any position between said first and said second position, and wherein said light guiding element is adapted to couple said optoelectronic devices in any of said positions.

3. Device according to claim 1, wherein said first optoelectronic device is an optical transmitter and said second optoelectronic device is an optical receiver.

4. Device according to claim 1, wherein said first and second optoelectronic devices are optical transceivers.

5. Device according to claim 3, wherein said light guiding element is further adapted to radiate, at least in one position of said first and said second housing part, light emitted from said at least one optical emitter out of said hinge element.

6. Device according to claim 5, wherein said at least one optical transmitter is capable of emitting visible light.

7. Device according to claim 1, further comprising a light shielding element arranged on said hinge element, wherein said light shielding element shields at least a part of light emitted by one of said optoelectronic devices from being radiated outside of said hinge element at least in one position of said first and said second housing part.

8. Device according to claim 6, wherein said light guiding element and/or said light shielding element are arranged to be capable of forming an illumination pattern visible on the outside of said hinge element at least in one position of said first and said second housing part.

9. Device according to claim 1, wherein said device is one of:
a mobile phone;
a personal digital assistant, PDA;
a gaming terminal or mobile gaming terminal;
a personal navigation assistant, PNA; and
a notebook computer.

10. Device according to claim 1, wherein said first and said second electronic components comprise at least one of:
a central processing unit, CPU;
a memory unit;
a display;
control keys;
a camera module;
a wireless local area network, WLAN, module;
a Bluetooth module;
a cellular transceiver;
a microphone;
a speaker; and
vibra or other haptic devices.
